(19) United States
(12) Patent Application Publication
(10) Pub. No.: US 2025/0006585 A1
(43) Pub. Date: Jan. 2, 2025

(54) SEMICONDUCTOR PACKAGES WITH MULTIPLE TYPES OF CONDUCTIVE COMPONENTS

(71) Applicants: JCET Management Co., Ltd., Shanghai (CN); STATS ChipPAC Pte. Ltd., Singapore (SG)

(72) Inventors: Zhan YING, Shanghai (CN); Kai LIU, Jiangyin (CN); Yaqin WANG, Jiangyin (CN)

(21) Appl. No.: 18/740,630

(22) Filed: Jun. 12, 2024

(30) Foreign Application Priority Data
Jun. 30, 2023 (CN) 202310800665.X

(51) Int. Cl. H01L 23/373; H01L 23/00; H01L 25/18; H10B 80/00

(52) U.S. Cl. CPC H01L 23/373; H01L 24/13; H01L 24/14; H01L 24/16; H01L 25/18; H01L 24/32; H01L 24/73; H01L 2224/13111; H01L 2224/13147; H01L 2224/14505; H01L 2224/16227; H01L 2224/32225; H01L 2224/73204; H01L 2924/1431; H01L 2924/1436; H10B 80/00

(57) ABSTRACT

A semiconductor package comprises: a package substrate having a front surface and a rear surface, wherein the package substrate comprises: a plurality sets of front conductive patterns; a plurality sets of rear conductive patterns; and a plurality sets of interconnects electrically coupling the set of front conductive patterns with the set of rear conductive patterns, respectively; wherein the package substrate at least comprises a first thermal performance region and a second thermal performance region, wherein the first thermal performance region and the second thermal performance region have different thermal performances; a plurality sets of conductive components attached to the front surface and the rear surface of the package substrate and connected to the plurality sets of front conductive patterns and the plurality sets of rear conductive patterns, wherein the plurality sets of conductive components comprise: a set of first-type conductive components mounted to the first thermal performance region of the package substrate; and a set of second-type conductive components mounted to the second thermal performance region of the package substrate.

### TECHNICAL FIELD

The present application generally relates to semiconductor technologies, and more particularly, to a semiconductor package with multiple types of conductive components.

### BACKGROUND OF THE INVENTION

The wiring used for interconnection within a semiconductor chip is extremely fine, being of the order of a few microns, or less, in width. The ability to form such wires has made possible for semiconductor chips containing millions or more interconnected components. At some point, however, contacts are required between the chips and the outside world where working to such small tolerances of wiring is not possible.

In order for connecting semiconductor chips to external devices or systems, printed circuit boards (PCB), interposers, or other similar substrates are widely used for mounting the chips thereon, thereby forming semiconductor packages having bigger sizes. The wiring on a PCB is much coarser than on a chip, being typically measured in millimeters. It is not practical to connect chip wiring directly to PCB wiring. Therefore, an intermediate structure, capable of handling both ends of this wire-width spectrum, is needed.

An example of such a structure is a ball grid array (BGA). BGA packaging technology is a surface mounting technology applied to integrated circuits, which is commonly used to permanently fix devices such as microprocessors. The BGA package is an array on the bottom of a package substrate, and solder balls are used as input/output (I/O) terminals of the circuits and connected to a PCB.

The solder ball has the function of signal conduction, electrical connection, and heat conduction. In the existing BGA package, the solder balls on the package substrate are generally the same. The larger the solder ball, the stronger the heat transfer capability. However, at the same time, the larger the solder ball, the larger the substrate area occupied, which is contrary to the high density and high pin output of the BGA. Therefore, a need exists for further improvement to semiconductor packages.

### SUMMARY OF THE INVENTION

An objective of the present application is to provide a semiconductor package structure with improved heat dissipation efficiency.

According to an aspect of the present application, a semiconductor package is disclosed. The semiconductor package comprises: a package substrate having a front surface and a rear surface, wherein the package substrate comprises: a plurality sets of front conductive patterns formed on the front surface; a plurality sets of rear conductive patterns formed on the rear surface; and a plurality sets of interconnects electrically coupling the set of front conductive patterns with the set of rear conductive patterns, respectively; wherein the package substrate at least comprises a first thermal performance region and a second thermal performance region, wherein the first thermal performance region and the second thermal performance region have different thermal performances; a plurality sets of conductive components attached to the front surface and the rear surface of the package substrate and connected to the plurality sets of front conductive patterns and the plurality sets of rear conductive patterns, wherein the plurality sets of conductive components comprise: a set of first-type conductive components mounted to the first thermal performance region of the package substrate, wherein the set of first-type conductive components is connected to a portion of the front conductive patterns and the rear conductive patterns; and a set of second-type conductive components mounted to the second thermal performance region of the package substrate, wherein the set of second-type conductive components are connected to a portion of the front conductive patterns and the rear conductive patterns.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1 to 3 illustrate a semiconductor package according to an embodiment of the present application. FIG. 1 is a cross-sectional view of the package. FIG. 2 is a front view of the package substrate and FIG. 3 is a rear view of the package substrate.

FIGS. 4 and 5 illustrate a semiconductor package according to another embodiment of the present application. FIG. 4 is a cross-sectional view of the package substrate. FIG. 5 is a rear view of the package substrate.

FIG. 6 illustrates a package substrate of a semiconductor package according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another clement(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

The inventors of the present application have found that, due to increased integration, many semiconductor packages will mount multiple semiconductor chips on a same substrate, or mount an electronic component package integrated with multiple circuit functional parts on a same substrate. These different semiconductor chips or circuit functional parts often have different power consumptions, which lead to different requirements of heat dissipation capabilities. When heat is generated by the semiconductor chips and the package, most of the heat is transferred to the outside of the semiconductor packages through the package substrate where they are located, but package structures are generally made of epoxy resin and filler and other low thermal conductivity materials. Therefore, when the semiconductor chips, due to a long time of operation, produce a lot of heat, the package structures may not be able to conduct heat in time, resulting in the heat being trapped in the chips or the substrate. At the same time, heat trapped in the semiconductor package may cause thermal deformation of the substrate, and the substrate may have different compositions (such as interconnects, usually copper, and polymers such as epoxy or similar insulation material) in different areas of the substrate, these different materials cause that the substrate of the semiconductor package may have different thermal stress distribution during operation of the semiconductor package.

In order to resolve at least one of the problems described above, a multiple-type conductive component array is proposed by the inventors of the present application to interconnect electronic components or electronic component package with the package substrate. For example, conductive components with copper cores or material with similar relatively high thermal conductivity may be used, as well as conductive components such as solder balls mainly made of a material with lower thermal expansion coefficient (such as resin). These conductive components with high thermal conductivities may establish thermal paths with improved heat dissipation capability for the semiconductor package, and solder balls with a lower thermal expansion coefficient can reduce the effect of thermal stress on the solder ball joints, thereby reducing significantly the risk of failures of the solder ball joints due to accumulated heat for the semiconductor packages.

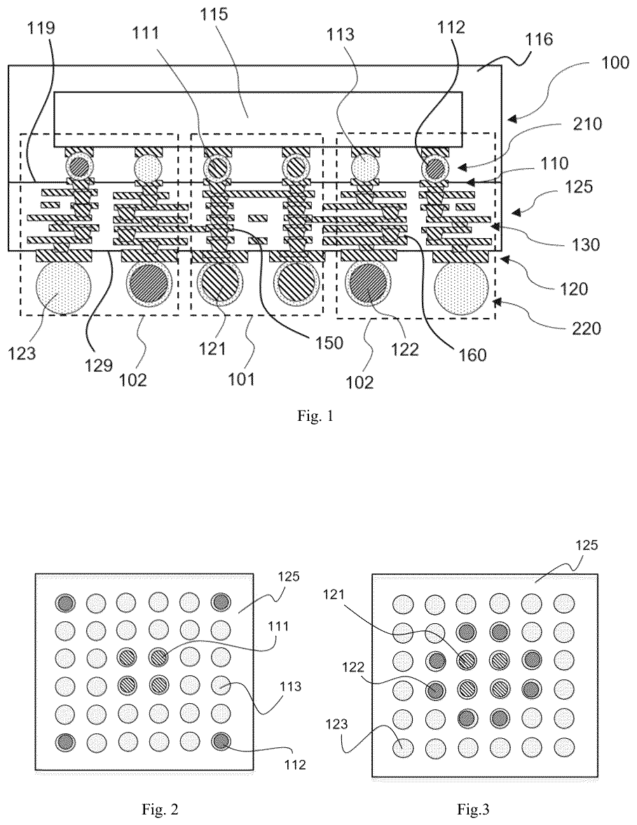

FIGS. 1 to 3 illustrate a semiconductor package 100 according to an embodiment of the present application. FIG. 1 is a cross sectional view of the semiconductor package 100, FIG. 2 is a front view of a package substrate of the semiconductor package 100 and FIG. 3 is a rear view of the package substrate of the semiconductor package 100.

As shown in FIG. 1, the semiconductor package 100 includes a package substrate 125 having a front surface 119 and a rear surface 129. The package substrate 125 may include one or more insulating layers, which may be interleaved with one or more conductive layers. It can be appreciated that the package substrate 125 can include any number of conductive and insulating layers interleaved over each other. The insulating layer may include ceramic, plastic, glass, or any other suitable insulating materials. The conductive layers, along with other internal conductive structures such as vias, form interconnects 130 embedded within the package substrate 125. The interconnects 130 may be formed of copper, for example.

The package substrate 125 further includes a set of front conductive patterns 110, such as contact pads, formed on the front surface 119, and a set of rear conductive patterns 120, such as contact pads, formed on the rear surface 129. The front and rear conductive patterns may be respective end surfaces of a set of interconnects 130 embedded in the insulating layer of the package substrate 125, which are exposed from either the front surface 119 or the rear surface 129. The set of interconnects 130 can electrically couple the set of front conductive patterns 110 with the set of rear conductive patterns 120, respectively. In some embodiments, the interconnects 130 may include conductive wiring or vias to route signals through the insulating layer, as aforementioned.

At least one electronic component 115 is mounted on the front surface 119 of the package substrate 125. The electronic component or components can be in the form of a semiconductor die or dice. In some embodiments, the at least one electronic component 115 may include one or more digital chips, analog chips or mixed signal chips, such as application-specific integrated circuit (“ASIC”) chips, sensor chips, wireless and radio frequency (RF) chips, memory chips, logic chips, or voltage regulator chips. In some other embodiments, the at least one electronic component 115 may also include one or more passive electrical components such as resistors, capacitors, inductors, etc. In the embodiment shown in FIG. 1, the electronic component 115 is a semiconductor die or chip with multiple input/output ports, each of which is required to be electrically coupled to an external device for signal or power transmission.

The semiconductor package 100 further includes a set of front solder balls 210 and a set of rear solder balls 220. As front conductive components and rear conductive components, the front solder balls 210 and the rear solder balls 220 are electrically connected to the set of front conductive patterns 110 and the set of rear conductive patterns 120, respectively. The electronic component 115 is electrically coupled to the set of front conductive patterns 110 via the set of front solder balls 210 to establish electrical connection with the package substrate 125.

In particular, the front and rear solder balls 210 and 220 can be deposited on the package substrate 125 in the form of balls or similar structures. As can be seen from FIG. 1, a first pitch between two adjacent solder balls of the front solder balls 210 can be increased to a second pitch between two adjacent solder balls of the rear solder balls 220, because there is more space on the package substrate 125, especially when the interconnects 130 can provide for redistribution of the wiring. Accordingly, the set of rear solder balls 220 may have a size that is greater than a size of the set of front solder balls 210. In other words, the layout of the solder balls on the rear surface 129 is exaggerated than the layout of the solder balls on the front surface 119. The bigger layout of solder balls allows for possibility of better heat dissipation. In some embodiments, the number of solder balls in the set of front solder balls 210 may be equal to the number of solder balls in the set of rear solder balls 220 as illustrated in the embodiments of FIGS. 1 to 3. In a variant, the number of solder balls in the front solder balls 210 and the number of solder balls in the rear solder balls 220 are different, for example, two or more solder balls of the front solder balls 210 may be coupled to a solder ball of the rear solder balls 220, or two or more rear solder balls of the rear solder balls 220 may be coupled to a solder ball of the front solder balls 210.

The set of front solder balls 210 include at least two types of solder balls, i.e., a plurality of first-type solder balls 111 and a plurality of second-type solder balls 112. Similarly, the set of rear solder balls 220 also include at least two types of solder balls, i.e., a plurality of first-type solder balls 121 and a plurality of second-type solder balls 122. In the illustrated embodiments, the first-type solder balls 111, 121 can include a copper core and a soldering material coating outside the copper core, while the second-type solder balls 112, 122 can be a conductive solder ball including a resin core and a solder material coating outside the resin core. In some other embodiments, the first-type solder balls 111, 121 may be made of other soldering material(s) that have better thermal conductivity. Compared to the second-type solder balls 112, 122, the first-type solder balls 111, 121 may have a greater thermal and electrical conductivity, therefore allowing better heat dissipation and lower electrical resistance. In some embodiments, the first-type solder balls 111, 121 are preferably located in a region of the electronic component 115 that consumes more power and generate more heat than the other regions of the electronic component 115, because more heat is required to be dissipated through the first-type solder balls 111, 121. For example, as shown in FIG. 1, the first-type solder balls 111, 121 are attached in a first thermal performance region 101 of the package substrate 125; Compared to other thermal performance regions of the package substrate 125, such as the second thermal performance region 102, the first thermal performance region 101 is required to provide better thermal conductivity performance to assist heat generated from the electronic component 115 dissipated to the outside the semiconductor package 100.

In some embodiments, the electronic component 115 is a semiconductor chip, which may have different circuit functional parts, such as a logic circuit part, a power circuit part, a control circuit part or a storage circuit part and so on. Among them, because complex operations such as logic operations are required, the logic circuit part usually has a relatively higher power consumption; and the power circuit part usually also has a relatively higher power consumption due to power supply and other requirements; while the control circuit or storage circuit has a relatively lower power consumption. Therefore, the first-type solder balls 111 and/or 121 can be arranged in a region of the electronic component 115 corresponding to the logic circuit part, the power circuit part, i.e., a region where the first thermal performance region 101 of the package substrate 125 corresponds to the logic circuit and/or power supply circuit and is attached; while the second-type solder balls 112 and/or 122 can be arranged in a region of the electronic component 115 corresponding to the control circuit or the storage circuit, i.e., a region where the second thermal performance region 102 of the package substrate 125 corresponds to the control circuit or storage circuit and is attached.

In some other embodiments, the first-type solder balls 111, 121 are preferably located in a region in the electronic component 115 that needs better heat dissipation than the other regions. For example, the first-type solder balls 111, 121 are at least located in a central region of the package substrate 125, the central region may be configured with electronic components with higher power consumption. Therefore, during operation, the electronic components may generate more heat than other regions of the package substrate 125. Furthermore, as mentioned above, the first-type solder balls 121 of the rear surface of the package substrate 125 can further improve the thermal conductivity capability of the semiconductor package 100, especially for those regions that require better heat dissipation. In some preferred embodiments, the first-type conductive components can be attached in pairs to the front surface and the back surface of the package substrate 125, so that the entire heat conduction path from the electronic component 115 to the outside of the semiconductor package 100 is made of a material having a relatively high thermal conductivity (typically the interconnects 130 may be made of copper or similar material with high thermal conductivity). It can be understood that the “in pairs” here refers to that the front conductive component(s) and the back conductive component(s) are connected by the same interconnection, but because the number of front conductive components or rear conductive components connected to the same interconnection may be different, “in pairs” does not require a one-to-one correspondence between a front conductive component and a rear conductive component. In addition, it should be noted that although it is preferred that all conductive components in the first thermal performance region can be the first-type solder balls, in some embodiments, a part of the conductive components mounted in the first thermal performance region can be the first-type solder balls, which at least partially enhance the thermal conductivity; while the remaining conductive components mounted in the first thermal performance region may be other types of solder balls, such as a tin solder ball formed solely of tin. Preferably, at least 50% of the conductive components in the first thermal performance region may be first-type solder balls, or more preferably at least 80% of the conductive components may be first-type solder balls.

Although thermal conductivity may be a factor desired to be considered for the multiple types of solder balls mounted on the package substrate 125, some other problems caused by heat accumulation need to be considered as well. As mentioned above, at least one set of the sets of front solder balls 210 and the set of rear solder balls 220 may further include one or more second-type solder balls, which may be made at least partially of a material having a thermal expansion coefficient larger than the first-type solder balls, or at least close to the substrate material (for example, resin) of the package substrate 125. For example, in the embodiment shown in FIG. 1, each set of the set of front solder balls 210 and the set of rear solder balls 220 includes a plurality of second-type solder balls 112 and/or 122. The second-type solder balls 112 and 122 both include a resin core coated by a soldering material. Such a type of solder balls allows to provide mechanical support and compensate mechanical stress produced within the semiconductor package 100, for example due to thermal expansion, because the resin core may compensate mechanical stress significantly. In some embodiments, the second-type solder balls are for example arranged in a region of the package substrate 125 where the density of interconnects 130 in the region is higher than in other regions, because denser interconnects may generate greater mechanical stress that needs to be compensated. For example, as shown in FIGS. 2 and 3, the second-type solder balls 122 of the set of rear solder balls 220 may be arranged surrounding the first-type solder balls 121 of the set of rear solder balls 220. In some other embodiments, the second-type solder balls may also be arranged on a region of the package substrate 125 in connection with the circuit functional parts with lower power consumption. In one embodiment, the second-type solder balls 112 of the set of front solder balls 210 are arranged at the corners of the electronic component 115 to compensate mismatch in thermal expansion between the electronic component 115 and the package substrate 125. In addition, the second-type solder balls 112 at the corners of the electronic component 115 can maintain a proper distance between the electronic component 115 and the package substrate 125 after a reflow process of the solder balls, thereby allowing the passage of the encapsulant material and avoiding the formation of voids or cavities in the encapsulant layer. In some embodiments, the second-type solder balls 112 may be located in a region below the electronic component 115 where a maximum mechanical stress is to be produced during use of the semiconductor package 100. Furthermore, the front or rear solder balls may include solder balls of other types, such as a tin solder ball, which may be formed at the other positions of the package substrate 125, such as attached at a region outside the first thermal performance region and the second thermal performance region to complete a BGA structure, for example. It can be understood that in some embodiments, other types of solder balls, such as tin solder balls, may also be attached in the first thermal performance region and the second thermal performance region, but do not completely replace the first-type solder balls or the second-type solder balls. For example, in the embodiment shown in FIG. 1, the second thermal performance region 102 includes partially tin solder balls 113 and 123. Although the embodiment shown in FIG. 1 only shows the first thermal performance region 101 and the second thermal performance region 102, in some other embodiments, the package substrate 125 may also include other thermal performance regions, which have a different thermal characteristics and a different thermal performance requirement from the first thermal performance region 101 and the second thermal performance region 102.

In some preferred embodiments, such as shown in FIGS. 1 to 3, each solder ball of the rear solder balls 220 is coupled to at least one solder ball of the front solder balls 210 via at least a pair of front and rear conductive patterns 110, 120 and interconnects 130 therebetween. In the embodiment of FIG. 1, each first-type solder ball 121 of the set of rear solder balls 220 is aligned vertically with one first-type solder ball 111 of the set of front solder balls 210, when viewed in a direction perpendicular to the front or rear surface 119, 129 of the package substrate 125. Accordingly, an interconnect path 150 connecting each first-type solder ball 121 of the set of rear solder balls 220 to one first-type solder ball 111 of the set of front solder balls 210 is substantially perpendicular to the package substrate 125. In this way, the interconnect path 150 connecting a first-type solder ball 121 of the set of rear solder balls 220 to a first-type solder ball 111 of the set of front solder balls 210 has a shorter total length of wiring or vias, and preferably a greater width, than other interconnect paths 160 interconnecting a second-type or an another-type solder ball of the set of rear solder balls 220 to a solder ball of the set of front solder balls 210, or interconnecting a second-type or an another-type solder ball of the set of front solder balls 210 to a solder ball of the set of rear solder balls 220. The interconnect path 150 has accordingly a better thermal and electrical conductivity, which may be helpful for heat dissipation for the region of the electronic component 115 that produce more heat during operation. It can be appreciated that, in some alternative embodiments, the interconnect path 150 connecting each first-type solder ball 121 of the set of rear solder balls 220 to one first-type solder ball 111 of the set of front solder balls 210 may not be perpendicular to the package substrate 125, because of the routing of the interconnects 130 in the package substrate 125 or other considerations. Nevertheless, the use of first-type solder balls 111 and 121 on both sides of the package substrate 125 allows for better heat transfer capability.

The semiconductor package 100 may further include at least one encapsulant layer 116 extending at least partially on the substrate 125 and covering the at least one electronic component 115. The encapsulant layer 116 may provide protection for the electronic component 115. In some embodiments, a shielding layer (not shown) may be further formed over the encapsulant layer 116 for electromagnetic interference shielding purpose.

In some embodiments, the electronic components encapsulated in the semiconductor packages may be other components such as chip-lets or other similar smaller packages.

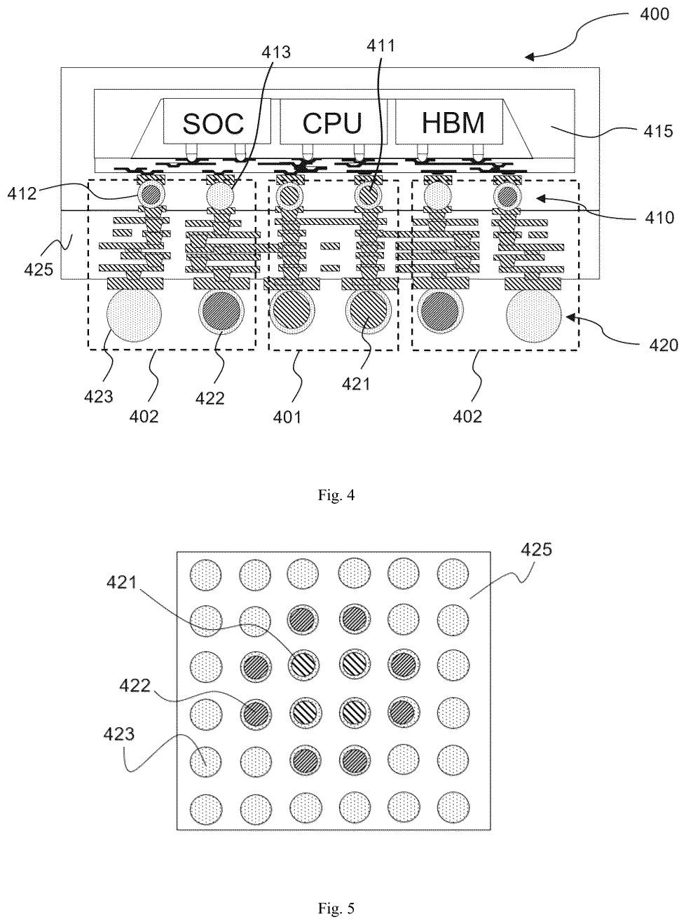

FIGS. 4 and 5 illustrate a semiconductor package 400 according to another embodiment of the present application. As shown in FIGS. 4 and 5, an electronic component 415 which in the form of a chip-let is mounted on a front surface of a package substrate 425 of the semiconductor package 400. The chip-let may include, as illustrated, several circuit functional modules, for example a System of Chip (SoC), a High-bandwidth Memory (HBM), and a central processing unit (CPU) module. These circuit functional modules are packaged in the semiconductor package 400 as the respective circuit functional parts of the semiconductor package 400.

Different types of conductive components can be mounted on the front surface and the rear surface of the package substrate 425, based on which thermal functional part is connected to the conductive components. It can be understood that, the thermal functional part of the electronic component 415 mainly depends on the circuit function therein, such as a logic circuit part, a power circuit part, a control circuit part or a storage circuit part and so on. Among them, because complex operations such as logic operations are required, the logic circuit part usually has a relatively higher power consumption; and the power circuit part usually also has a relatively higher power consumption due to power supply and other requirements; while the control circuit or storage circuit has a relatively lower power consumption. Accordingly, the circuit functional part having a relatively higher power consumption usually has a relatively higher heat dissipation requirement, and the circuit functional part having a relatively lower power consumption usually has a relatively lower heat dissipation requirement.

For example, a set of front conductive components, such as solder balls 410 arc mounted on a front surface of the package substrate 425. The front solder balls 410 include, below a logic circuit functional region below a central region of the package substrate 425, a plurality of first-type solder balls 411 coupled respectively to a first-type solder ball 421 belonging to the set of rear solder balls 420 to provide better thermal and electrical conductivity. The first-type solder balls 411 and 421 may include a copper core and a soldering material coating outside the copper core. Other thermal performance region 402 on the package substrate 425 may be mounted with second-type solder balls 412, 422, which include a resin core and a soldering material coating outside the resin core, in a manner similar to the semiconductor package 100 shown in FIGS. 1 to 3, which will not be elaborated herein. It can be understood that other types of solder balls, such as tin solder balls 413 and 423, can also be partially disposed in the region 402 and/or other regions.

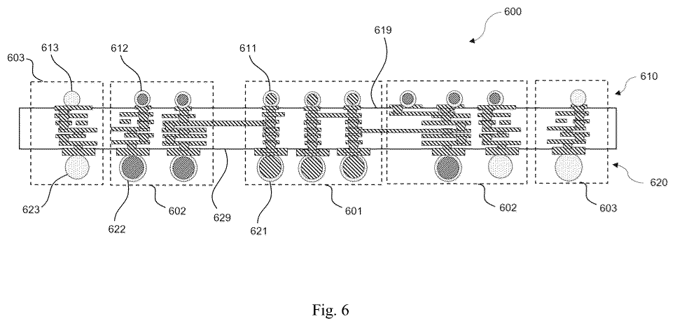

FIG. 6 shows a package substrate 600 for a semiconductor package according to another embodiment of the present application. The package substrate 600 can be used to mount various electronic components, and can be further attached to other substrates or devices to transfer connections of the electronic components thereon to these other substrates or devices. In some embodiments, the front surface 619 of the package substrate 600 is used for mounting electronic components, while the rear surface 629 of the package substrate 600 is used for attaching the package substrate 600 to other substrates or devices.

As shown in FIG. 6, the package substrate 600 includes multiple regions that have different thermal properties. For example, the first thermal performance region 601 located at the central position of the package substrate 600 is mainly used for mounting electronic components with relatively high heat dissipation requirements, such as logic circuit chips; the second thermal performance region 602 adjacent to the first thermal performance region 601 can be used for mounting other electronic components, which may generate less heat than logic circuit chips during operation, such as power chips; the third thermal performance region 603 located at the outermost of the package substrate 600 can be used for mounting other electronic components, such as control chips or passive components (such as switching devices or connectors). Generally speaking, compared with the third thermal performance region 603, the second thermal performance region 602 may have conductive interconnections (such as a redistribution layer) with a relatively higher density. The conductive interconnections are usually made of a metal material or an alloy material, which has a higher thermal expansion rate than other dielectric materials (such as resin materials) in the package substrate, so it is susceptible to large deformation after being heated.

For the first thermal performance region 601 with relatively high heat dissipation requirements, conductive components with relatively good thermal conductivity and electrical conductivity can be arranged on the front surface and the rear surface of the package substrate 600, such as conductive pillars or copper core solder balls, just as copper core solder balls 611 and 621 shown in FIG. 6. Preferably, copper core solder balls or other conductive components with relatively good thermal conductivity and electrical conductivity can be used in all of the first thermal performance region 601, or conductive components with relatively good thermal conductivity and electrical conductivity can be used in this region 601 at a certain ratio, such as more than 30%, more than 40%, more than 50%, more than 60%, more than 70%, more than 80% or more than 90%. Optionally, for the first thermal performance region 601, conductive components with relatively good thermal conductivities and electrical conductivities may be provided only on one of the front surface or the rear surface of the package substrate 600.

For the second thermal performance region 602, since there are usually conductive interconnects with a relatively high density (for example, compared to the third thermal performance region 603), the front surface and/or rear surface of the package substrate 600 in this region can use resin core solder balls 612 and 622, or other solder balls or conductive components with reduced metal ratio. The conductive component has a relatively low thermal expansion coefficient than metal solder balls, thereby reducing the shear stress generated in the package substrate 600 under temperature changes, and avoiding solder joints from breaking due to shear stress. Preferably, solder balls or conductive components with a reduced metal ratio can be used in all of the second thermal performance region 602, or solder balls or conductive components with a reduced metal ratio can be used in this region 602 at a certain ratio, such as more than 30%, more than 40%, more than 50%, more than 60%, more than 70%, more than 80% or more than 90%.

For the third thermal performance region 603, the electronic components mounted thereon usually have relatively low heat dissipation requirements, and the density of the conductive interconnects contained therein is also relatively low, so conventional conductive components can be used in this region, for example, tin solder balls 613 or 623 as shown in FIG. 6. Tin solder balls can strengthen the contact area between the solder balls and the chip, and between the solder balls and other substrates, thus enhancing the soldering strength and avoiding the breakage of solder joints caused by external force.

While the semiconductor package of the present application is described in conjunction with corresponding figures, it will be understood by those skilled in the art that modifications and adaptations to the semiconductor package may be made without departing from the scope of the present invention.

The discussion herein includes numerous illustrative figures that show various portions of a semiconductor package. For illustrative clarity, such figures do not show all aspects of each example semiconductor package. Any of the example semiconductor packages provided herein may share any or all characteristics with any or all other semiconductor packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package, comprising:
a package substrate having a front surface and a rear surface, wherein the package substrate comprises:
a plurality sets of front conductive patterns formed on the front surface;
a plurality sets of rear conductive patterns formed on the rear surface; and
a plurality sets of interconnects electrically coupling the set of front conductive patterns with the set of rear conductive patterns, respectively;
wherein the package substrate at least comprises a first thermal performance region and a second thermal performance region, wherein the first thermal performance region and the second thermal performance region have different thermal performances;
a plurality sets of conductive components attached to the front surface and the rear surface of the package substrate and connected to the plurality sets of front conductive patterns and the plurality sets of rear conductive patterns, wherein the plurality sets of conductive components comprise:
a set of first-type conductive components mounted to the first thermal performance region of the package substrate, wherein the set of first-type conductive components are connected to a portion of the front conductive patterns and the rear conductive patterns; and
a set of second-type conductive components mounted to the second thermal performance region of the package substrate, wherein the set of second-type conductive components are connected to a portion of the front conductive patterns and the rear conductive patterns.

2. The semiconductor package of claim 1, wherein the first-type conductive components comprise a conductive copper pillar, or a conductive solder ball having a copper core and a soldering material coating outside the copper core.

3. The semiconductor package of claim 1, wherein the first-type conductive components are attached to the front surface and the rear surface of the package substrate in pairs.

4. The semiconductor package of claim 1, wherein the second-type conductive components comprise a conductive solder ball having a resin core and a soldering material coating outside the resin core.

5. The semiconductor package of claim 1, wherein the plurality sets of conductive components comprise a tin solder ball attached to a region of the package substrate outside the first thermal performance region and the second thermal performance region.

6. The semiconductor package of claim 1, wherein the first thermal performance region of the package substrate is used for mounting a first electronic component, and the second thermal performance region of the package substrate is used for mounting a second electronic component, wherein a power consumption of the first electronic component is higher than that of the second electronic component.

7. The semiconductor package of claim 6, wherein the first electronic component comprises a logic circuit electronic component or a power circuit electronic component, and the second electronic component comprises a control circuit electronic component.

8. The semiconductor package of claim 5, wherein the first thermal performance region of the package substrate is used for mounting a first electronic component, and the second thermal performance region of the package substrate is used for mounting a second electronic component, wherein a region of the package substrate outside the first thermal performance region and the second thermal performance region is used for mounting other electronic components, and wherein a heat dissipation requirement of the first electronic component is higher than that of an electronic component other than the first electronic component.

9. The semiconductor package of claim 1, wherein a density of interconnects in the second thermal performance region of the package substrate is higher than that of interconnects in a region of the package substrate outside the second thermal performance region.
